(19) United States
(12) Patent Application Publication
(10) Pub. No.: US 2026/0076123 A1
(43) Pub. Date: Mar. 12, 2026

(54) HIGH ASPECT RATIO ETCH WITH A LINER

(71) Applicant: Lam Research Corporation, Fremont, CA (US)

(72) Inventors: Amit MUKHOPADHYAY, Fremont, CA (US); Qing XU, Fremont, CA (US); Merrett WONG, Palo Alto, CA (US); Ilya PISKUN, Pleasanton, CA (US); Gregory Clinton VEBER, Oakland, CA (US); Yongsik YU, Northridge, CA (US); Francis Sloan ROBERTS, Portland, OR (US); Ragesh PUTHENKOVILAKAM, Portland, OR (US); Kapu Sirish REDDY, Portland, OR (US)

(21) Appl. No.: 19/105,217

(22) PCT Filed: Aug. 22, 2023
(86) PCT No.: PCT/US2023/030869

§ 371 Date: Feb. 20, 2025

Related U.S. Application Data
(60) Provisional application No. 63/400,914, filed on Aug. 25, 2022.

(51) Int. Cl. H01L 21/311; H01L 21/02

(52) U.S. Cl. CPC H10P 50/73; H10P 14/6336

(57) ABSTRACT

A method for etching features in a stack is provided. A patterned mask is formed over the stack. Features are partially etched in the stack through the patterned mask. A helmet mask is deposited over the patterned mask and liner on sidewalls of the features. The stack is etched through the helmet mask.

### CROSS-REFERENCE TO RELATED APPLICATION

This application claims the benefit of priority of U.S. Application No. 63/400,914, filed Aug. 25, 2022, which is incorporated herein by reference for all purposes.

### BACKGROUND

The disclosure relates to a method of forming semiconductor devices on a semiconductor wafer.

In forming semiconductor devices, etch layers may be etched to form memory holes or lines or other semiconductor features. Some semiconductor devices may be formed by etching a single stack of silicon dioxide also known as silicon oxide (SiO₂), for example, to form a capacitor in dynamic access random memory (DRAM). Other semiconductor devices may be formed by etching stacks of bilayers of alternating silicon dioxide (oxide) and silicon nitride (nitride) (ONON), or alternating silicon dioxide and polysilicon (OPOP). Other stacks of alternating layers may be etched. Some of the stacks of alternating layers may have one of the layers of the alternating layers that is silicon oxide. Some alternating layers may be alternating trilayers. Such stacks may be used in memory applications and three dimensional “not and” gates (3D NAND). These stacks tend to require relatively high aspect ratio (HAR) etching of the dielectrics. For high aspect ratio etches, examples of desired etch characteristics are high etch selectivity to the mask (such as an amorphous carbon mask), low sidewall etching with straight profiles, and high etch rate at the etch front. Some high aspect ratio etches result in tapered features that are much wider at the top than the bottom. Such features may increase device failure or limit device density, device performance, and device depth.

In some etch processes of an OPOP stack with an amorphous carbon mask, during the etch, a metal containing passivant is used during the etch process. The metal containing passivant may be provided during the etch process so that passivation and etching occur simultaneously or there may be alternating steps of passivation and etching. It has been found that when a tungsten (W) passivation is used, the tungsten selectively deposits on the polysilicon with respect to the silicon oxide so that there is less passivation on the silicon oxide than on the polysilicon. The reduced passivation of silicon oxide results in increased defects, such as increased CD and notching. The weakest or thinnest deposition dictates the ability of the passivation layer to protect the underlying material. For example, once the thinner deposition on the oxide degrades during additional etching, the oxide can begin to be etched even if the Si still has tungsten passivation. The etching of the oxide causes CD to increase as well as additional defect formation such as notching, keyholes, etc. Non-uniform passivation may also cause profile twisting, kink, and ion sided bowing.

In another manifestation, a method for etching features in a stack is provided. A patterned mask is formed over the stack. Features are partially etched in the stack through the patterned mask. A tapered liner is deposited on the sidewalls of the features, wherein the tapered liner is thicker near tops of the features and thinner nearer bottoms of the features. The stack is etched.

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack is provided. A patterned mask is formed over the stack. Features are partially etched in the stack through the patterned mask. A helmet mask is deposited over the patterned mask and liner on sidewalls of the features. The stack is etched through the helmet mask.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of processes used in some embodiments.

FIGS. 2A-E are schematic cross-sectional views of a stack processed according to some embodiments.

FIGS. 3A-C are cross-sectional views of a stack processed according to some embodiments.

FIG. 4 is a schematic view of an etch chamber that may be used in some embodiments.

FIG. 5 is a schematic view of a computer system that may be used in practicing some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Dry development of high aspect ratio contacts requires strict control of the tapering angle of the sidewall. Various methods try to limit lateral critical dimension (CD) differences between the top and bottom parts of the etched structures. With the recent development of 3D NAND memory having thicker structures with an increased number of ONON or OPOP bilayers, the demand for tight control of top and bottom geometries is especially significant. In case the profile (difference between the top and bottom CDs) increases, subsequent steps of device manufacturing will be at risk that will impact device performance. In the current technology, reactive ion etching of high aspect ratio structures relies on sidewall deposition to protect against CD lateral erosion. A delicate balance between etching and sidewall deposition is especially difficult to maintain for high aspect ratio features. As a result, high aspect ratio dry development is limited to thinner structures and requires significant complex development to enable a thick stack to be etched.

### Non-Touchdown Embodiments

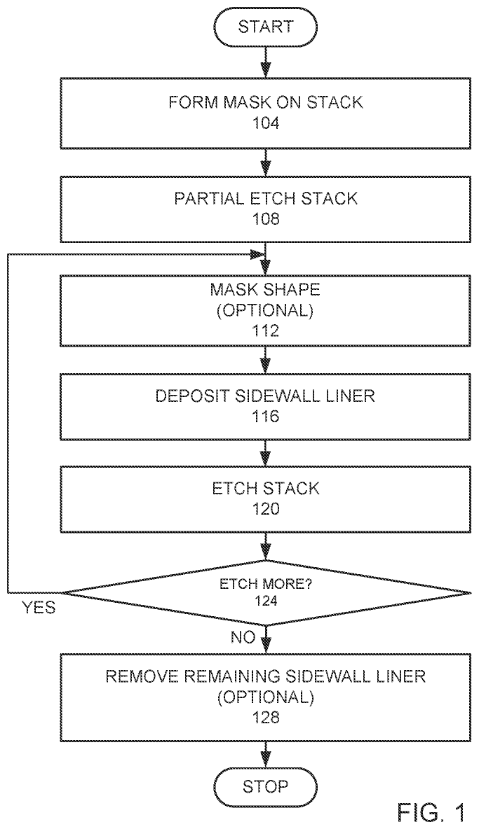

Embodiments described herein provide deeper high aspect ratio features etched in a stack, where widths of the features near the top of the features are about equal to widths of the features near the bottoms of the features. To facilitate understanding, FIG. 1 is a high level flow chart that may be used in some embodiments. A mask is deposited on a stack (step 104). In some embodiments, the mask is a metal or metalloid containing mask. In some embodiments, a plasma enhanced physical vapor deposition (PECVD) is used to deposit a metal containing dielectric film that may be used as a mask. A method of using PECVD to deposit a tungsten carbide film is described in U.S. Pat. No. 9,875,890, entitled “Deposition of Metal Dielectric Film for Hardmask,” issued on Jan. 23, 2018, which is incorporated by reference for all purposes and may be used in some embodiments. In some embodiments, the deposited tungsten carbide film is patterned to form a mask. In some embodiments, the mask is a carbon containing amorphous carbon mask. In some embodiments, the mask is metal and metalloid free in order to prevent metal or metalloid contamination.

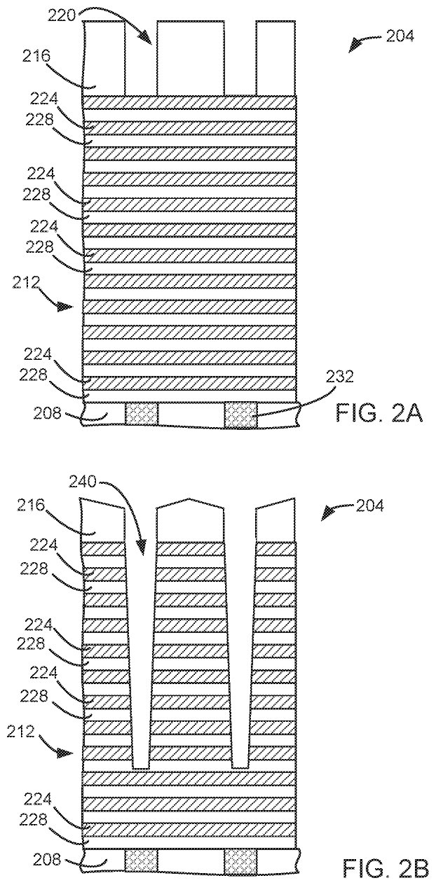

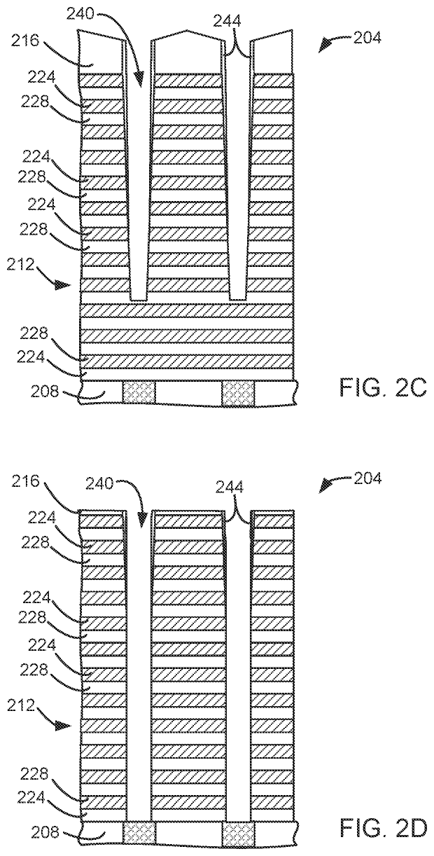

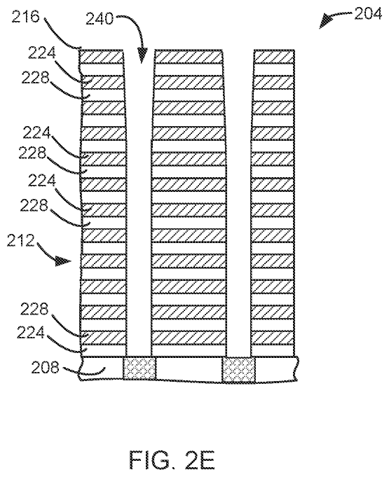

FIG. 2A is a schematic cross-sectional view of a stack 204 that may be etched in some embodiments. In some embodiments, the stack 204 comprises a substrate 208 under a plurality of bilayers 212 disposed below a patterned mask 216. In some embodiments, one or more layers may be disposed between the substrate 208 and the plurality of bilayers 212 and/or the plurality of bilayers 212 and the patterned mask 216. In some embodiments, the patterned mask 216 is an amorphous carbon mask. In some embodiments, the patterned mask pattern provides mask features 220 for high aspect ratio contacts. In some embodiments, the mask features 220 are formed before the stack 204 is placed in the etch chamber. In other embodiments, the mask features 220 are formed while the stack 204 is in the etch chamber. In some embodiments, each bilayer 212 includes a layer of silicon oxide 224 and a layer of silicon nitride 228. Conductive contacts 232 are in the substrate 208.

The stack is partially etched (step 108). In some embodiments, an etching gas is provided. In some embodiments, RF power is provided to transform the etching gas into a plasma with etching ions. A voltage is applied to accelerate etching ions from the plasma to the stack The etching ions partially etch the stack and etch some of the mask. The etching of the stack may comprise at least one of a chemical etching and physical sputtering of the stack.

FIG. 2B is a schematic cross-sectional view of a stack 204 after the stack 204 has been partially etched forming etched features 240. Part of the mask 216 has been etched away. During the partial etch, the patterned mask 216 is partially etched. In some embodiments, as shown in FIG. 2B the partial etching does not etch until touchdown.

An optional mask shaping may be provided (step 112). In some embodiments where the mask is a carbon containing mask, a hydrogen based plasma chemistry is used to shape the mask. In some embodiments, an oxygen based plasma chemistry is used to shape the mask.

A liner is deposited on the sidewalls of the partially etched features (step 116). In some embodiments, the liner is deposited using at least one of a chemical vapor deposition (CVD) or plasma enhanced chemical vapor deposition (PECVD) process. In some embodiments, no liner is deposited near the bottom of the partially etched features. The sidewall liners help prevent bowing. In some embodiments, the liner is a carbon containing liner. In some embodiments, during the deposition of the liner, some of the deposition is deposited on top of the patterned mask to form helmet masks on the patterned mask. In some embodiments, a CVD or PECVD deposition of carbon containing liners uses precursors of at least one of an alkane, alkene, and alkyne hydrocarbon along with specific temperatures and pressures in order to provide the deposition selectivity and provided a tapered liner shape. In some embodiments, the liner is tapered where the liner is thicker near the top of the etch features and thinner closer to the bottom of the etched features where the liner thickness approaches zero. In some embodiments, the tapered liner is the thickest at the top of the features and thinnest near the bottom of the liner closest to the bottom of the etched features. In addition to carbon, some liners further comprise hydrogen. In some embodiments, the percentage of hydrogen may be used to provide desired liner hardness.

FIG. 2C is a schematic cross-sectional view of a stack 204 after liners 244 have been deposited on the sidewalls of the partially etched features 240 (step 116). The liners 244 are tapered being thicker near the top of the partially etched features 240.

The stack is then further etched (step 120). In some embodiments, the further etching is more aggressive than the partial etching of the stack. FIG. 2D is a schematic cross-sectional view of a stack 204 after the stack 204 is further etched (step 120). In some embodiments, the liner 244 and some of the patterned mask 216 are etched away. In some embodiments, the etching of the stack is continued until the etching of the stack is completed, as shown in FIG. 2D.

In some embodiments, the providing the liner allows for the use of a more aggressive etch causing the widening of the bottoms of the features, reducing the feature taper. The liner allows a more aggressive etch by protecting the sidewalls near the top of the partially etched features, reducing bowing while allowing sidewalls near the bottoms of the features to be etched in order to reduce tapering. One major issue during high aspect ratio (HAR) etch is CD scaling, specifically as desired features become vertically scaled there is a simultaneous push to keep lateral feature size constant. In practice, this can be very difficult to achieve and many of the current technologies have tradeoffs. In some embodiments, a liner is utilized to allow for CD control and prevent other defect formation, such as notching.

If further etching is required (step 124) the process may return to the optional mask shaping step (step 112) or the deposition of a new sidewall liner (step 116). If no additional etching is needed (step 124), then an optional step of removing the remaining sidewall liner 244 and/or remaining patterned mask 216 (step 128) is provided. In some embodiments, an oxygen containing plasma may be used to remove a carbon containing liner (244) and patterned mask 216. FIG. 2E is a schematic cross-sectional view of a stack 204 after the remaining liner 244 and patterned mask 216, shown in FIG. 2D, have been removed.

Some embodiments may be used on an Oxide/Nitride (ONON) multilayer stack to form features, such as contact holes or trenches, in making a 3D NAND memory device. Some embodiments may be used for dynamic random access memory (DRAM) Capacitor etching. Some embodiments may be used to etch silicon oxide and polysilicon bilayers (OPOP). Some embodiments provide an etch depth of greater than 1 micron. In some embodiments, the etch depth is greater than 10 microns.

An advantage of some embodiments is the ability of a device manufacturer to be able to have a more precise control of the profile of a high aspect feature. Various embodiments enable increasing the bottom CD for very high aspect features. Various embodiments enable the next generations of devices that rely on deeper structures with higher aspect ratios. Various embodiments reduce the cost of device manufacturing by reducing the number of steps for the development of high aspect ratio contacts. Various embodiments reduce the variation of the width of the features along the depth of the features so that the difference between widths at any two points along the depth of the features 240 is less than 10%. In some embodiments, the deposition of the sidewall liner also deposits a helmet mask.

In some embodiments, the stack may be a single silicon containing layer, such as a single layer of silicon oxide, silicon nitride, or silicon. In some embodiments, the stack may comprise a single layer or multiple layers of other silicon containing materials. In some embodiments, the patterned mask 216 or liner 244 may contain a metal or metalloid dopant. In some embodiments, for etching a stack with a silicon layer, the mask may further comprise oxygen. In some embodiments, for etching a silicon oxide stack, the mask may further comprise silicon. Some embodiments may have metal or metalloid dopant. In some embodiments, the metal in the metal or metalloid dopant is at least one of tungsten, molybdenum, ruthenium, tantalum, titanium, platinum, and aluminum. In other embodiments, the metalloid is boron.

### Touchdown Embodiments

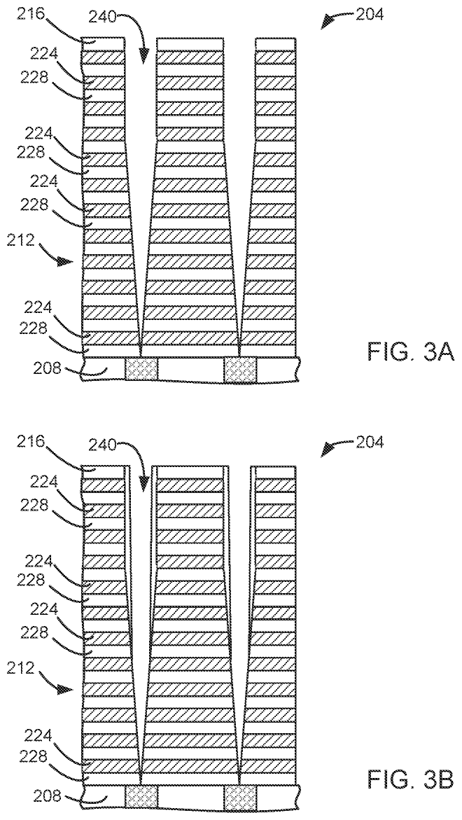

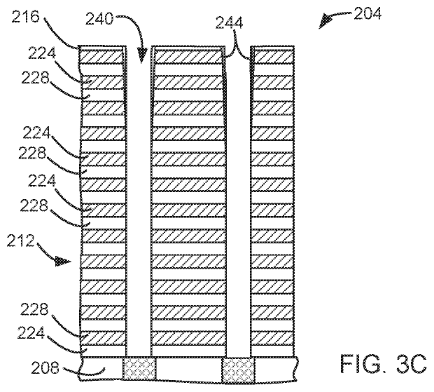

In some embodiments, the features 240 may be etched the entire depth of the stack (i.e., close to touchdown) during the partial etch (step 108), before the liner 244 is deposited. FIG. 3A is a schematic cross-sectional view of the stack 204 after the stack 204 has been partially etched to touchdown forming etched features 240 in another embodiment where the initial stack is shown in FIG. 2A. During the partial etch, the patterned mask 216 is partially etched. Although the etched features 240 have been etched to touchdown, the etched features are significantly tapered. In some embodiments, the touchdown etch etches to the substrate 208, so that the etched features are etched to the completed depth. In some embodiments, the etched features 240 from the partial etch are close to touchdown by being less than 1 micron from touchdown. In some embodiments, the etched features 240 from the partial etch are close to touchdown by being less than 1.5 microns from touchdown.

A liner is deposited on the sidewalls of the etched features 240 (step 116). FIG. 3B is a schematic cross-sectional view of a stack 204 after liners 244 have been deposited on the sidewalls of the partially etched features 240 (step 116). The liners 244 are tapered being thicker near the tops of the partially etched features 240 and thinner closer to the bottom of the etched features 240.

The stack is further etched (step 120). Since the etched features 240 are etched to touchdown during the partial etch (step 108), the further etch does not etch the etched features deeper, but instead widens the tapered bottoms of the etched features 240. FIG. 3C is a schematic cross-sectional view of a stack 204 after the partial etch (step 108). The bottoms of the etched features 240 are widened. Some of the liner 244 and patterned mask 216 are etched away.

If no additional etching is needed (step 124), then an optional step of removing the remaining sidewall liner 244 and/or remaining patterned mask 216 (step 128) is provided. In some embodiments, an oxygen containing plasma may be used to remove a carbon containing liner (244) and patterned mask 216. FIG. 3D is a schematic cross-sectional view of a stack 204 after the remaining liner 244 and patterned mask 216, shown in FIG. 3D, have been removed.

In some embodiments, the timing and process of the deposition of the sidewall liner may be used to tailor the mask deposition to the desired resulting features, such as reduced bow CD, improved bottom CD, reduced taper, reduced twisting, and reduced defect formation. In some embodiments, the helmet mask and sidewall liners synergistically improve feature profiles.

The liners are able to allow for thinner patterned masks 216. For example, in some embodiments, the liner allows for the etching of etched features that are 2.5 microns deep using a mask that is 0.5 microns thick. In some embodiments, the liner allows for the etching of etched features that are 6 microns deep using a mask that is 2 microns thick. In some embodiments, the use of the liner allows a process that does not require mask shaping, since the liner helps to avoid necking. In some embodiments, the thickness of the mask is no more than 34% of the thickness of the stack or the depth of the etched features.

In some embodiments where the partial etch has touchdown and a helmet deposition is provided, a process is provided where the patterned mask 216 thickness can be decreased by about 100 nm over the prior art. In some embodiments, where the partial etch does not touchdown, providing a helmet mask deposition with liners allows the patterned mask thickness to be decreased by between 200 nm to 600 nm over the prior art.

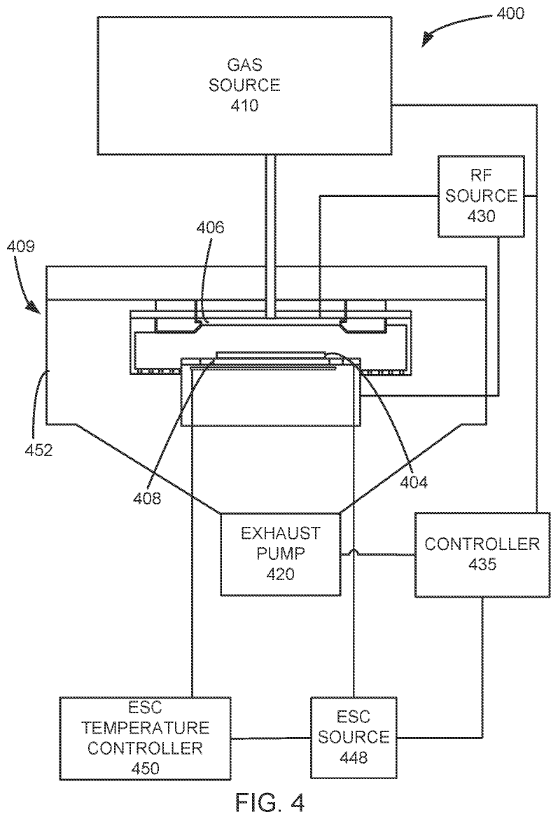

FIG. 4 is a schematic view of an etch reactor system 400 that may be used in some embodiments. In some embodiments, an etch reactor system 400 comprises a gas distribution plate 406 providing a gas inlet and an electrostatic chuck (ESC) 408, within an etch chamber 409, enclosed by a chamber wall 452. Within the etch chamber 409, a stack 404 is positioned over the ESC 408. The ESC 408 may provide a bias from the ESC source 448. An etch gas source 410 is connected to the etch chamber 409 through the gas distribution plate 406. An ESC temperature controller 450 is connected to the ESC 408. A radio frequency (RF) source 430 provides RF power to a lower electrode and/or an upper electrode, which in this embodiment are the ESC 408 and the gas distribution plate 406, respectively. In some embodiments, 400 kilohertz (kHz), 60 megahertz (MHz), and optionally, 2 MHz, 27 MHz power sources make up the RF source 430 and the ESC source 448. In some embodiments, the upper electrode is grounded. In some embodiments, one generator is provided for each frequency. In some embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 435 is controllably connected to the RF source 430, the ESC source 448, an exhaust pump 420, and the etch gas source 410. An example of such an etch chamber is the Flex™ etch system manufactured by Lam Research Corporation of Fremont, CA. The process chamber can be a CCP (capacitively coupled plasma) reactor or an ICP (inductively coupled plasma) reactor.

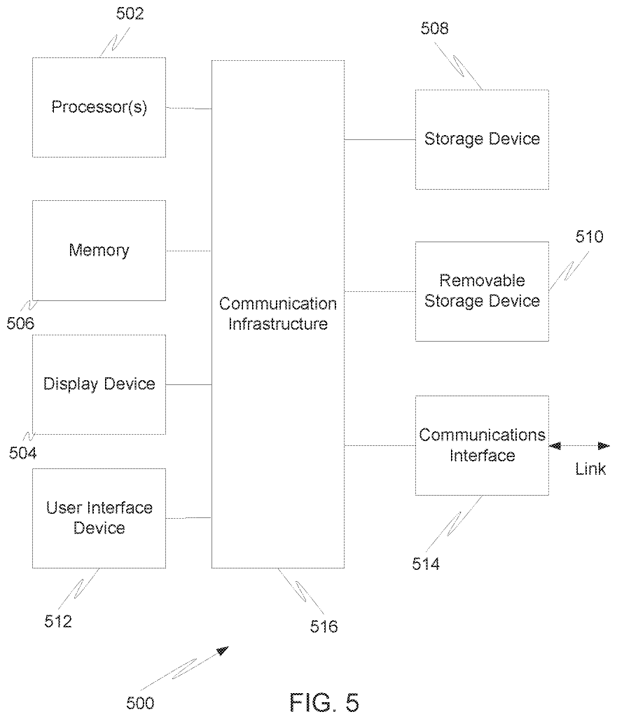

FIG. 5 is a high level block diagram showing a computer system 500, which is suitable for implementing the controller 435 used in embodiments. The computer system 500 may have many physical forms ranging from an integrated circuit, a printed circuit board, and a small handheld device up to a huge supercomputer. The computer system 500 includes one or more processors 502, and further can include an electronic display device 504 (for displaying graphics, text, and other data), a main memory 506 (e.g., random access memory (RAM)), storage device 508 (e.g., hard disk drive), removable storage device 510 (e.g., optical disk drive), user interface devices 512 (e.g., keyboards, touch screens, keypads, mice or other pointing devices, etc.), and a communications interface 514 (e.g., wireless network interface). The communications interface 514 allows software and data to be transferred between the computer system 500 and external devices via a link. The system may also include a communications infrastructure 516 (e.g., a communications bus, cross-over bar, or network) to which the aforementioned devices/modules are connected.

Information transferred via communications interface 514 may be in the form of signals such as electronic, electromagnetic, optical, or other signals capable of being received by communications interface 514, via a communications link that carries signals and may be implemented using wire or cable, fiber optics, a phone line, a cellular phone link, a radio frequency link, and/or other communications channels. With such a communications interface 514, it is contemplated that the one or more processors 502 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that is executed by a computer using an interpreter. Computer readable media may also be computer code transmitted by a computer data signal embodied in a carrier wave and representing a sequence of instructions that are executable by a processor.

In some embodiments, the partial etch, subsequent etch, and the mask shaping may be performed in one or more etch chambers, and the selective deposition of the helmet and sidewall liner and the mask shaping is done in a separate CVD or PECVD chamber. An oxygen containing plasma may be used for mask shaping in the etch chambers. A hydrogen containing plasma may be used for mask shaping in a CVD or PECVD chamber. In some embodiments, the partial etch, subsequent etch, mask shaping, and deposition of the helmet mask and sidewall liner are performed in-situ in a single process chamber that is able to both etch and provide a CVD or PECVD process.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack, comprising:
a) forming a patterned mask over the stack;
b) partially etching features in the stack through the patterned mask;
c) depositing a helmet mask over the patterned mask and liner on sidewalls of the features; and
d) etching the stack through the helmet mask.

2. The method, as recited in claim 1, wherein the liner comprises at least one of carbon, a metal, and a metalloid.

3. The method as recited in claim 1, wherein the depositing the liner is deposited simultaneously with depositing the helmet mask.

4. The method, as recited in claim 1, further comprising shaping the patterned mask after partially etching features the stack and before depositing the helmet mask.

5. The method, as recited in claim 1, wherein the liner is tapered being thicker near tops of the features and thinner nearer bottoms of the features.

6. The method, as recited in claim 5, wherein the liner does not extend to bottoms of the features.

7. The method, as recited in claim 1, wherein the helmet mask and tapered liner comprise amorphous carbon.

8. The method, as recited in claim 1, wherein the stack is a silicon oxide containing stack.

9. The method, as recited in claim 1, wherein the partially etching features etches the features to touchdown and wherein the etching the stack through the helmet mask widens bottoms of the features.

10. The method as recited in claim 1, wherein the partially etching features does not etch features to touchdown and forms partially etched tapered features and wherein the etching the stack through the helmet mask reduces taper of the tapered features.

11. A method for etching features in a stack, comprising:
a) forming a patterned mask over the stack;
b) partially etching features in the stack through the patterned mask;
c) depositing a tapered liner on sidewalls of the features, wherein the tapered liner is thicker near tops of the features and thinner nearer bottoms of the features; and
d) etching the stack.

12. The method, as recited in claim 11, wherein the tapered liner comprises at least one of carbon, a metal, and a metalloid.

13. The method, as recited in claim 11, wherein the tapered liner does not extend to bottoms of the features.

14. The method, as recited in claim 11, wherein the tapered liner comprises amorphous carbon.

15. The method, as recited in claim 11, wherein the stack is a silicon oxide containing stack.

16. The method, as recited in claim 11, wherein the partially etching features etches the features to touchdown and wherein the etching the stack widens bottoms of the features.

17. The method, as recited in claim 11, wherein the partially etching features does not etch features to touchdown and forms partially etched tapered features and wherein the etching the stack reduces taper of the tapered features.

18. The method, as recited in claim 11, wherein the patterned mask has a thickness of less than 0.5 microns and the stack has a thickness of at least 2.5 microns.

19. The method, as recited in claim 11, wherein the etching the stack is more aggressive than the partially etching features.

20. The method, as recited in claim 11, wherein the patterned mask has a thickness and the stack has a thickness, wherein the thickness of the patterned mask is no more than 34% of the thickness of the stack.
